(19) United States
(12) Patent Application Publication
(10) Pub. No.: US 2014/0147973 A1
(43) Pub. Date: May 29, 2014

(54) METHOD OF PACKAGING POWER DEVICES AT WAFER LEVEL

(71) Applicant: Samsung Electronics Co., Ltd., Suwon-si (KR)

(72) Inventors: Hyuk-soon CHOI, Hwaseong-si (KR); Hong-Pyo HEO, Yongin-si (KR); Jong-seob KIM, Hwaseong-si (KR); Jai-kwang SHIN, Anyang-si (KR); Jae-joon OH, Seongnam-si (KR); In-jun HWANG, Hwaseong-si (KR)

(21) Appl. No.: 13/938,580

(22) Filed: Jul. 10, 2013

(30) Foreign Application Priority Data
Nov. 26, 2012 (KR) 10-2012-0134866

(51) Int. Cl. H01L 23/00

(52) U.S. Cl. CPC H01L 24/81
USPC 438/124

(57) ABSTRACT

A method of packaging power devices at a wafer level is disclosed. The method includes preparing a wafer having a plurality of nitride power devices thereon, each of the plurality of nitride power devices having a plurality of electrodes thereon; forming a polymer layer on the plurality of nitride power devices; exposing each of the electrodes from the polymer layer; forming a solder bump on the exposed electrodes; forming a molding layer covering the solder bump on the polymer layer; and removing the wafer and exposing the solder bump.

### CROSS-REFERENCE TO RELATED APPLICATIONS

This application claims priority under 35 U.S.C. §119 to Korean Patent Application No. 10-2012-0134866, filed on Nov. 26, 2012, in the Korean Intellectual Property Office, the disclosure of which is incorporated herein in its entirety by reference.

### BACKGROUND

1. Field

Example embodiments relate to methods of removing a wafer having power devices formed thereon while packaging the wafer.

2. Description of the Related Art

A power conversion system may require a device controlling current flow through an ON/OFF switch; i.e., a power device. In the power conversion system, the efficiency of the power device may affect the efficiency of the whole system.

Most power devices that are currently commercially available are silicon-based power device such as a power metal-oxide-semiconductor field-effect transistor (MOSFET) or a power insulated gate-bipolar transistor (IGBT). The limitations in physical properties and manufacturing processes of silicon (Si) may make it difficult to increase the efficiency of a Si-based power device. To overcome these limitations, studies or developments intended to increase the conversion efficiency by applying a III-V compound semiconductor to a power device have been performed. In regard to this, a high electron mobility transistor (HEMT) using a heterojunction structure of the compound semiconductor has come to prominence.

A HEMT may include semiconductor layers having different electric polarization characteristics. In the HEMT, one semiconductor layer having a relatively high polarity may allow 2-dimensional electron gas (2DEG) to be induced at the other adjacent semiconductor layer, and the induced 2DEG may have a high electron mobility.

When a high voltage is applied to a HEMT, current may leak to a lower substrate having a low critical electric field, so that breakdown may occur in the lower substrate. A power device from which the lower substrate is removed may enhance the breakdown voltage.

In the case where a plurality of power devices are formed on a wafer and then the wafer is removed, the power devices may be easily damaged. The damage may be due to a small thickness and a handling issue may also be caused. An operation of forming a separate support substrate on the power devices may make the manufacturing process complicated.

### SUMMARY

Example embodiments relate to methods of removing a wafer while power devices are packaged at a wafer level.

Additional aspects will be set forth in part in the description which follows and, in part, will be apparent from the description, or may be learned by practice of example embodiments.

According to example embodiments, a method of packaging power devices at a wafer level includes: preparing a wafer having a plurality of nitride power devices formed thereon, each of the plurality of nitride power devices having a plurality of electrodes formed thereon; forming a polymer layer on the plurality of nitride power devices; exposing each of the electrodes from the polymer layer; forming a solder bump on the exposed electrode; forming a molding layer covering the solder bump on the polymer layer; and removing the wafer and exposing the solder bump.

In example embodiments, the exposing of the electrode may include forming first holes exposing each of the electrodes from the polymer layer, and the forming of the solder bump may include forming the solder bump on the first holes.

In example embodiments, the exposing of the solder bump may include disposing an electrical connection plate formed with a contact corresponding to the solder bump on the molding layer, and the removing of the wafer may be performed as a subsequent process.

In example embodiments, the electrical connection plate may be a printed circuit board or an interposer.

In example embodiments, the polymer layer may be formed in a thickness range of about 30 nm to 1 μm.

In example embodiments, the polymer layer may include a polymer or a dielectric.

In example embodiments, the molding layer may be formed in a thickness range of about 30 μm to 3 mm.

In example embodiments, the molding layer may include an epoxy.

According to example embodiments, a method of packaging a power device in a wafer level includes: preparing a wafer having a plurality of nitride power devices formed thereon, each of the a plurality of nitride power devices having a source electrode, a drain electrode and a gate electrode formed therein; forming a polymer layer on the a plurality of nitride power devices; exposing the source electrode and the gate electrode from the polymer layer; forming a solder bump on the exposed electrode; forming a molding layer covering the solder bump on the polymer layer; removing the wafer and exposing the solder bump; forming an insulating layer under the a plurality of nitride power devices; forming a via hole exposing the drain electrode from the insulating layer; and forming a metal thin layer electrically connected to the drain electrode on the insulating layer.

### BRIEF DESCRIPTION OF THE DRAWINGS

The above and other features and advantages of example embodiments will become apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIGS. 1A through 1D are cross-sectional views sequentially illustrating a method of forming power devices at a wafer level, according to example embodiments;

FIGS. 2A and 2B are cross-sectional views illustrating a method of forming power devices at a wafer level, according to example embodiments;

FIGS. 3A through 3E are cross-sectional views sequentially illustrating a method of forming power devices at a wafer level according to example embodiments; and

FIGS. 4A and 4B are cross-sectional views illustrating a method of forming power devices at a wafer level, according to example embodiments.

### DETAILED DESCRIPTION

Example embodiments will now be described more fully with reference to the accompanying drawings, in which some example embodiments are shown. Example embodiments may, however be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”. As used herein the term “and/or” includes any and all combinations of one or more of the associated listed items. Expressions such as “at least one of,” when preceding a list of elements, modify the entire list of elements and do not modify the individual elements of the list.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be orientated “above” the other elements or features. Thus, the exemplary term “below” can encompass both an orientation of above and below. The device may be otherwise orientated (rotated 90 degrees or at other orientations) and the spatially relative descriptors used herein interpreted accordingly.

The terminology used herein is for the purpose of describing particular embodiments only and is not intended to limit example embodiments. As used herein, the singular forms “a,” “an” and “the” are intended to include the plural forms as well, unless the context clearly indicates otherwise. It will be further understood that the terms “comprises” and/or “comprising,” when sued in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as being limited to the particular shapes of regions illustrated herein and are to include deviations in shapes that result, for example, from manufacturing. For example, an implanted region illustrated as a rectangle will have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, methods of removing a wafer having power devices formed thereon while packaging the wafer, according to example embodiments, will be described more fully with reference to the accompanying drawings.

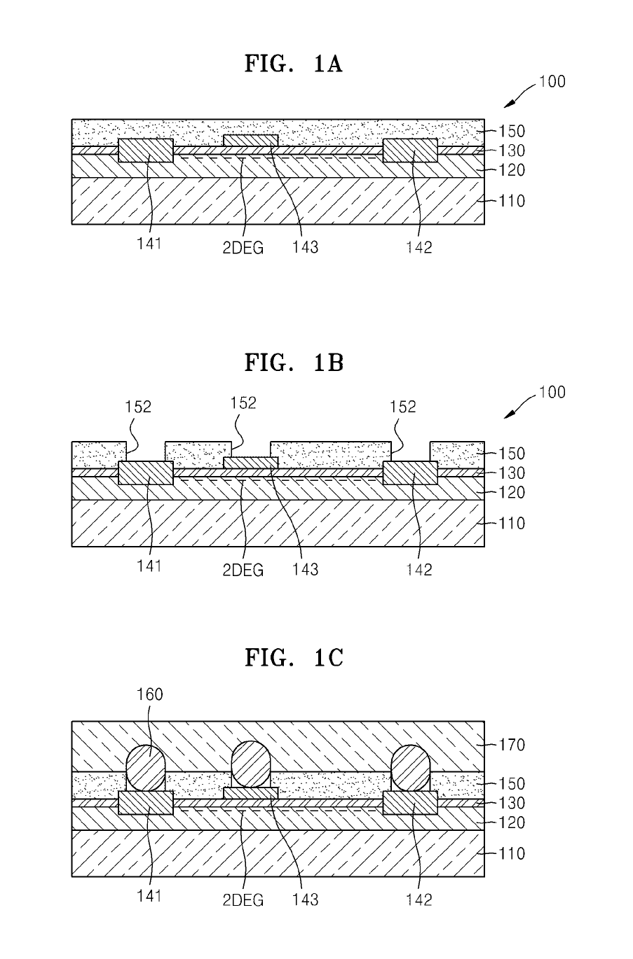

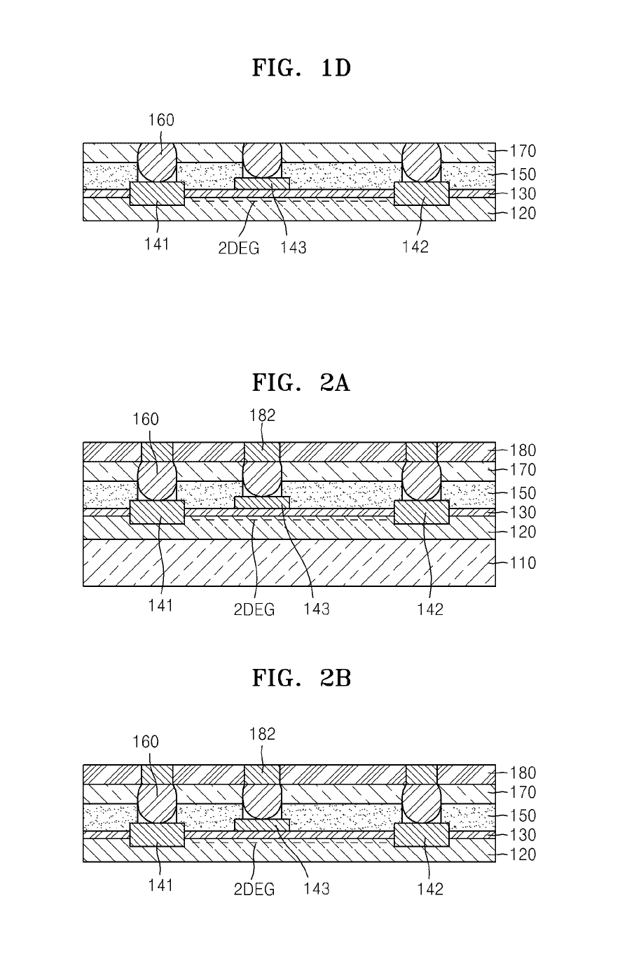

FIGS. 1A through 1D are cross-sectional views sequentially illustrating a method of forming power devices at a wafer level, according to example embodiments.

Referring to FIG. 1A, a wafer having a plurality of power devices is prepared. A method of forming a plurality of power devices on a wafer is well known in the art, therefore a detailed description thereof is omitted. A high electron mobility transistor (HEMT) 100 as a power device is illustrated in FIG. 1A. However, example embodiments are not limited to the HEMT. For example, another power device such as an insulated gate-bipolar transistor (IGBT) or the like may be formed.

While a plurality of power devices may be formed on the wafer, a description will be made with one HEMT 100 for convenience. The wafer may be called a substrate 110 hereinafter.

A channel layer 120 may be formed on a substrate 110. The substrate 110 may be made of, for example, sapphire, glass, Si, or the like. However, this is only exemplary, and the substrate 110 may be made from various different materials as well as the above-mentioned materials.

The channel layer 120 may be made of a first nitride semiconductor material. The first nitride semiconductor material may be a III-V compound semiconductor material. For example, the channel layer 120 may be a GaN-based material layer or a GaAs layer. As an example, the channel layer 120 may be a GaN layer. In this case, the channel layer 120 may be an undoped GaN layer, or may be an impurity-doped GaN layer.

Although not illustrated in the drawings, a buffer layer may be further provided between the substrate 110 and the channel layer 120. The buffer layer may buffer a difference in lattice constant and a difference in thermal expansion coefficient between the substrate 110 and the channel layer 120 to prevent the crystallinity from deteriorating. The buffer layer may include a nitride containing at least one of aluminum (Al), gallium (Ga), indium (In), and boron (B), and may have a single-layered or multi-layered structure. The buffer layer may be made of, for example, AIN, GaN, AlGaN, InGaN, AlInN, or AlGaInN. A seed layer (not illustrated) for growth of the buffer layer may be further provided on the substrate 110.

A channel supply layer 130 may be formed on the channel layer 120. The channel supply layer 130 may allow 2-dimensional electron gas (2DEG) to be induced at the channel layer 120. The 2DEG may be formed in the channel layer 120 under an interface between the channel layer 120 and the channel supply layer 130. The channel supply layer 130 may be made of a second nitride semiconductor material, which may be different from the first nitride semiconductor material constituting the channel layer 120. The second nitride semiconductor material may be different in one of polarity characteristic, energy bandgap, and lattice constant from the first nitride semiconductor material. Specifically, the second nitride semiconductor material may be higher in at least one of polarity and energy bandgap than the first nitride semiconductor material.

The channel supply layer 130 may include a nitride containing at least one of Al, Ga, In, and B, and may have a single-layered or multi-layered structure. As an example, the channel supply layer 130 may be made of AlGaN, AlInN, InGaN, AIN, or AlInGaN. In the case where the channel layer 120 is made of GaAs, the channel supply layer 130 may be made of AlGaAs. The channel supply layer 130 may be an undoped layer or an impurity-doped layer. The channel supply layer 130 may have a thickness that is not more than a few ten nanometers, for example. For example, the channel supply layer 130 may be about 50 nm thick, but it is not limited thereto.

A source electrode 141 and a drain electrode 142 may be formed on the channel layer 120 at both sides of the channel supply layer 130. The source electrode 141 and the drain electrode 142 may be electrically connected to the 2DEG. The source electrode 141 and the drain electrode 142 may be formed on the channel supply layer 130. As seen in FIG. 1, the source electrode 141 and the drain electrode 142 may be formed to penetrate the channel layer 120. In addition, the structure of the source electrode 141 and the drain electrode 142 may be changed variously.

A gate electrode 143 may be formed on the channel supply layer 130 between the source electrode 141 and the drain electrode 142. The gate electrode 143 may include various metal materials or metal compounds.

A gate insulating layer may be further formed between the channel supply layer 130 and the gate electrode 143.

A polymer layer 150 covering the gate electrode 143 may be formed on the substrate 110. The polymer layer 150 may be formed to a thickness in a range of about 30 nm to 1 μm. The polymer layer 150 may be formed by spin-coating a polymer. The polymer layer 150 may be formed by depositing a dielectric, for example, silicon oxide.

Referring to FIG. 1B, first holes 152 may be formed in the polymer layer 150 to expose each of the source, drain, and gate electrodes 141, 142, and 143 of the HEMT 100. The forming of the first holes 152 may be performed by using a photolithography method, and detailed description thereof will be omitted.

Referring to FIG. 1C, solder bumps 160 may be formed in the first holes 152. The solder bumps 160 may be formed in a size range of about a few ten μm to a few hundred μm. The solder bumps 160 may be disposed in each of the first holes 152 by using a machine, or may be formed by forming a metal in each of the first holes 152 using an electrical plating method and then thermally treating the metal. The first holes 152 in the polymer layer 150 may limit the formation region of the solder bumps 160.

A molding layer 170 covering the solder bumps 160 may be formed on the polymer layer 150. The molding layer 170 may be formed in a thickness range of about 30 μm to 3 mm. The molding layer 170 may be formed by spin-coating or screen-printing an epoxy. Thereafter, the molding layer 170 may be thermally treated and hardened.

Referring to FIG. 1D, the substrate 110 is removed. Since the substrate 110 may have a thickness of about a few hundred μm, the substrate 110 may first be made to be about ten or less μm thick by a mechanical grinding. Thereafter, the remaining substrate 110 may be etched and completely removed.

The molding layer 170 may also be grinded to expose the solder bumps 160. The grinding of the molding layer 170 may be performed by a chemical-mechanical planarization or a mechanical grinding.

The grinding of the molding layer 170 may be performed prior to the removing of the substrate 110.

By the above-mentioned method, a plurality of power devices packaged at a wafer level may be manufactured. Thereafter, the manufactured power devices may be separated into individual power device packages through a dicing process.

According to example embodiments, the method of manufacturing a plurality of power devices may be simplified, because a molding member in a wafer level packaging is used as a support member instead of a separate support member. Also, since the positions of solder bumps may be limited by the polymer and then a molding layer may be formed thereon, the forming of the solder bumps may be easier.

FIGS. 2A and 2B are cross-sectional views illustrating a method of forming power devices at a wafer level, according to example embodiments.

Since the operations of FIGS. 1A through 1C equivalently apply to the example embodiments, detailed description thereof will be omitted.

Referring to FIG. 2A, the molding layer 170 in the resultant structure of FIG. 1C may be ground to expose the solder bumps 160. The grinding of the molding layer 170 may be performed by a chemical-mechanical planarization or a mechanical grinding.

An electrical connection plate 180 may be disposed on the molding layer 170. Since the electrical connection plate 180 has contacts 182 to correspond to the solder bumps 160, the contacts 182 may be electrically connected to the solder bumps 160. The contacts 182 may be connected to an electrical wire formed on the electrical connection plate 180. The electrical connection plate 180 may be a printed circuit board (PCB) or an interposer.

Referring to FIG. 2B, the substrate 110 may be removed. Since the substrate 110 may have a thickness of about a few hundred μm, the substrate 110 may first be made to be about ten or less μm thick by a mechanical grinding in order to remove the substrate 110. Thereafter, the remaining substrate 110 may be etched and completely removed.

While the above example embodiments describe that the electrical connection plate 180 may be disposed and then the substrate 110 may be removed, the example embodiment is not limited thereto. For example, after the substrate 110 may first be removed, the grinding of the molding layer 170 and the disposing of the electrical connection plate 180 may be performed.

By the above-mentioned method, a plurality of power devices packaged at a wafer level may be manufactured. Thereafter, the manufactured power devices may be separated into individual power device packages through a dicing process.

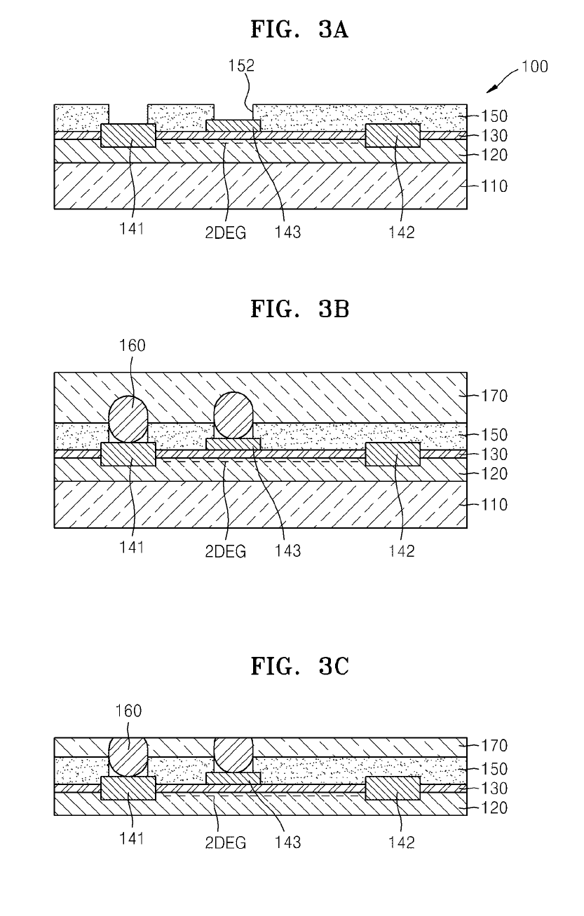

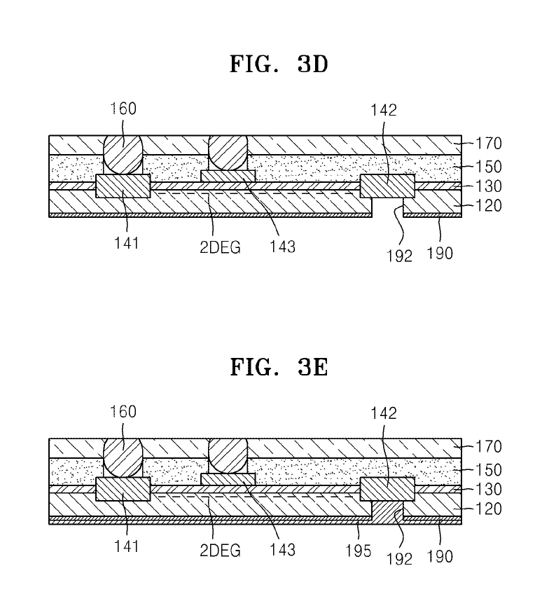

FIGS. 3A through 3E are cross-sectional views sequentially illustrating a method of forming power devices at a wafer level, according to example embodiments.

Since the operation of FIG. 1A equivalently may apply to example embodiments, detailed description thereof will be omitted

Referring to FIG. 3A, first holes 152 may be formed in the polymer layer 150 to expose the source and gate electrodes 141 and 143 of the HEMT 100 in the resultant structure of FIG. 1A. The forming of the first holes 152 may be performed by using a photolithography method, and detailed description thereof will be omitted.

Referring to FIG. 3B, solder bumps 160 may be formed in the first holes 152. The solder bumps 160 may be formed in a size range of about a few ten μm to a few hundred μm. The solder bumps 160 may be disposed in each of the first holes 152 by using a machine, or may be formed by forming a metal in each of the first holes 152 through an electrical plating method and then thermally treating the metal.

A molding layer 170 covering the solder bumps 160 may be formed on the polymer layer 150. The molding layer 170 may be formed in a thickness range of about 30 μm to 3 mm. The molding layer 170 may be formed by spin-coating or screen-printing an epoxy. Thereafter, the molding layer 170 may be thermally treated and hardened.

Referring to FIG. 3C, the substrate 110 may be completely removed. Since the substrate 110 may have a thickness of about a few hundred μm, the substrate 110 may first be made to be about ten or less μm thick by a mechanical grinding in order to remove the substrate 110. Thereafter, the remaining substrate 110 may be etched and completely removed.

The molding layer 170 may be ground to expose the solder bumps 160. The grinding of the molding layer 170 may be performed by a chemical-mechanical planarization or a mechanical grinding.

The molding layer 170 may be ground prior to the removing of the substrate 110.

Referring to FIG. 3D, an insulating layer 190, for example, an AIN layer, may be formed to a thickness of about a few ten nanometers on a bottom surface of the channel layer 120. The AIN layer 190 may be formed by performing a general deposition method. The AIN layer 190 may be an insulating layer but has high heat conductivity.

The insulating layer 190 and the channel layer 120 may be sequentially etched to form a second hole 192 exposing the drain electrode 142.

Referring to FIG. 3E, a metal thin layer 195 filling the second hole 192 may be formed on the insulating layer 190. The metal thin layer 195 may be electrically connected to the drain electrode 142. The metal thin layer 195 may be a common electrode connected to drain electrodes of the plurality of power devices. The metal thin layer 195 may be formed of gold (Au), tin (Sn), or the like.

By the above-mentioned method, a plurality of power devices packaged at a wafer level may be manufactured. Thereafter, the manufactured power devices may be separated into individual power device packages through a dicing process.

Since a drain electrode pad in the power device may be formed on a surface facing the surface where the source electrode and the gate electrode may be formed, it may be easy to install an electrical connection at the drain electrode where high voltage is applied to.

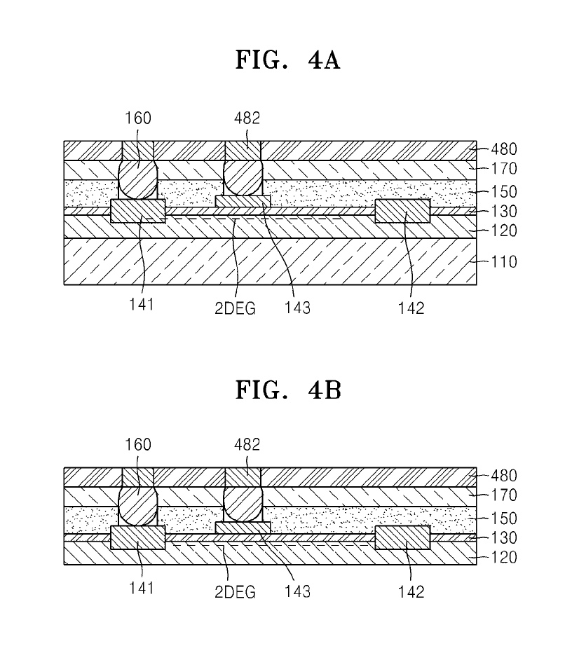

FIGS. 4A and 4B are cross-sectional views illustrating a method of forming power devices at a wafer level, according to example embodiments.

Since the operations of FIGS. 3A and 3B may equivalently apply to example embodiments, detailed description thereof will be omitted.

Referring to FIG. 4A, the molding layer 170 in the resultant structure of FIG. 3B may be ground to expose the solder bumps 160. The grinding of the molding layer 170 may be performed by a chemical-mechanical planarization or a mechanical grinding.

An electrical connection plate 480 may be disposed on the molding layer 170. Since the electrical connection plate 480 may have contacts 482 that correspond to the solder bumps 160, the contacts 482 may be electrically connected to the solder bumps 160. The electrical connection plate 480 may be a PCB or an interposer.

Referring to FIG. 4B, the substrate 110 may be removed. Since the substrate 110 may have a thickness of about a few hundred μm, the substrate 110 may first be made to be about ten or less μm thick by a mechanical grinding in order to remove the substrate 110. Thereafter, the remaining substrate 110 may be etched and completely removed.

While the above example embodiments describe that the electrical connection plate 480 may be disposed and then the substrate 110 may be removed, the example embodiments are not limited thereto. For example, after the substrate 110 may first be removed, the grinding of the molding layer 170 and the disposing of the electrical connection plate 480 may be performed.

Since the subsequent operations of forming an insulating layer and forming a thin metal layer may be substantially the same as those disclosed in FIGS. 3D and 3E, detailed description thereof will be omitted.

According to the above example embodiments, the method of manufacturing a plurality of power devices may be simplified, because a molding member in a wafer-level packaging may be used as a support member instead of a separate support member.

Also, since the positions of the solder bumps may be limited by the polymer and then the molding layer may be formed, the forming of the solder bumps may be easier.

It should be understood that example embodiments having thus been described should be considered in a descriptive sense only and not for purposes of limitation. Descriptions of features or aspects within each method according to example embodiments should typically be considered as available for other similar features or aspects in other methods according to example embodiments. For example, one skilled in the art knows that the structure of a method shown in FIGS. 1A through 4B may be variously modified. Therefore, while some example embodiments have been particularly shown and described, it will be understood by one of ordinary skill in the art that variations in form and detail may be made therein are not to be regarded as a departure from the intended spirit and scope of example embodiments, and all such modifications as would be obvious to one skilled in the art are intended to be included within the scope of the following claims.

What is claimed is:

1. A method of packaging power devices at a wafer level, comprising:
preparing a wafer having a plurality of nitride power devices thereon, each of the plurality of nitride power devices having a plurality of electrodes thereon;
forming a polymer layer on the plurality of nitride power devices;
exposing each of the plurality of electrodes from the polymer layer;
forming a solder bump on each of the plurality of exposed electrodes; and
forming a molding layer covering the solder bump on the polymer layer.

2. The method of claim 1, further comprising:
removing the wafer and exposing the solder bump.

3. The method of claim 1, wherein
the exposing each of the plurality of electrodes includes forming a first hole exposing each of the plurality of electrodes from the polymer layer, and
the forming of the solder bump includes forming the solder bump on the first hole.

4. The method of claim 2, wherein
the exposing the solder bump includes disposing an electrical connection plate having a contact corresponding to the solder bump on the molding layer, and
the removing the wafer is performed as a subsequent process.

5. The method of claim 4, wherein the electrical connection plate is a printed circuit board (PCB) or an interposer.

6. The method of claim 1, wherein the polymer layer is in a thickness range of about 30 nm to about 1 μm.

7. The method of claim 1, wherein the polymer layer includes a polymer or a dielectric.

8. The method of claim 1, wherein the molding layer is in a thickness range of about 30 μm to about 3 mm.

9. The method of claim 1, wherein the molding layer includes an epoxy.

10. A method of packaging power devices at a wafer level, comprising:
preparing a wafer having a plurality of nitride power devices thereon, each of the plurality of nitride power devices having a source electrode, a drain electrode, and a gate electrode therein;
forming a polymer layer on the plurality of nitride power devices;
exposing the source electrode and the gate electrode from the polymer layer;
forming a solder bump on each of the exposed electrodes; and
forming a molding layer covering the solder bump on the polymer layer.

11. The method of claim 10, further comprising:
removing the wafer and exposing the solder bump.

12. The method of claim 11, further comprising:
forming an insulating layer under the plurality of nitride power devices;
forming a via hole in the insulating layer to expose the drain electrode; and
forming a metal thin layer electrically connected to the drain electrode on the insulating layer.

13. The method of claim 10, wherein
the exposing of the source electrode and the gate electrode includes forming a first hole exposing each of the source electrode and the gate electrode from the polymer layer, and
the forming of the solder bump includes forming the solder bump on the first hole.

14. The method of claim 11, wherein
the exposing of the solder bump includes disposing an electrical connection plate having a contact corresponding to the solder bump on the molding layer, and
the removing of the wafer is performed as a subsequent process.

15. The method of claim 14, wherein the electrical connection plate is a printed circuit board (PCB) or an interposer.

16. The method of claim 10, wherein the polymer layer is to a thickness range of about 30 nm to about 1 μm.

17. The method of claim 10, wherein the polymer layer includes a polymer or a dielectric.

18. The method of claim 10, wherein the molding layer is a thickness range of about 30 μm to about 3 mm.

19. The method of claim 10, wherein the molding layer includes an epoxy.

20. The method of claim 14, further comprising:
forming an insulating layer under the plurality of nitride power devices;
forming a via hole in the insulating layer to expose the drain electrode; and
forming a metal thin layer electrically connected to the drain electrode on the insulating layer.
